(19) United States
(12) Patent Application Publication
(10) Pub. No.: US 2010/0132978 A1
(43) Pub. Date: Jun. 3, 2010

(54) WHISKER-FREE COATING STRUCTURE AND METHOD OF FABRICATING THE SAME

(75) Inventors: Yee-Wen YEN, Taipei City (TW); Jinn P. Chu, Taipei City (TW); Chon-Hsin Lin, Taipei City (TW); Chun-Lei Hsu, Taipei City (TW); Chao-Kang Li, Taipei City (TW)

Correspondence Address: QUINTERO LAW OFFICE, PC, 615 Hampton Dr, Suite A202, Venice, CA, 90291, US

(73) Assignee: NATIONAL TAIWAN UNIVERSITY OF SCIENCE & TECHNOLOGY, TAIPEI CITY (TW)

(21) Appl. No.: 12/471,162

(22) Filed: May 22, 2009

(30) Foreign Application Priority Data
Dec. 3, 2008 (TW) TW97146879

(51) Int. Cl. H01B 5/00; C23C 14/35; C25D 5/00

(52) U.S. Cl. 174/126.2; 204/192.15; 205/184

(57) ABSTRACT

A whisker-free coating structure and a method for fabricating the same are disclosed. The whisker-free coating structure includes a substrate, a tungsten doped copper layer overlaying the substrate, and a lead-free tin layer overlaying the tungsten doped copper layer.

### BACKGROUND OF THE INVENTION

1. Field of the Invention

The invention relates to lead-free solder technologies and more particularly to lead-free solder technologies suppressing tin whiskers growth.

2. Description of the Related Art

Lead-frames comprising copper with high electrical conductivity are typically utilized as a main lead-frame material in electronic products using surface mount technology (SMT) for assembly. Further, metal copper is widely utilized in printed circuit boards as a substrate and wiring material. In some applications, copper substrates, wiring terminals or lead-frame surfaces are covered by tin-lead or solder alloys utilizing electroplating or hot dip coating for enhancing wetting abilities between the copper substrates, wirings or leads and solders, to improve the bonding abilities there between. Conventionally, the solder materials covering the copper substrates, wiring terminals or lead-frame surfaces are mainly a eutectic tin-lead (Sn-37Pb) alloy. Metal lead, however, is a heavy metal that not only pollutes the environment, but also negatively affects human health. As such, countries like the European Union (EU) has adopted standards such as the Waste Electrical and Electronic Equipment Directive (WEEE) and the Restriction of certain Hazardous Substances Directive (RoHS) that limit metal lead compositions in electronic products. Thus, lead-containing materials for electrical and electronic products are being replaced by lead-free materials. Therefore, it is necessary for domestic and international electronic product manufactures to replace conventional lead-containing assembly processes with lead-free assembly processes.

Conventional leaded devices mostly utilize copper or iron-nickel alloy materials. In lead-containing assembly processes, device leads are plated and covered by tin-lead alloys. In lead-free assembly processes, structures are replaced by copper lines or leads with high electrical conductivity covered by lead-free solders. Lead-free solder materials mostly utilize pure tin or tin-0.7 wt % copper alloy systems. While more environmentally friendly however, lead-free solder materials do have characteristic problems. Specifically, at room temperature, idiopathic tin whiskers growth occurs on the surfaces of lead-free solder materials. When the tin whiskers grow close to neighboring device leads, point discharge occurs thereto due to the high electric field, and sparks occur which may cause fires or device failure. When the tin whiskers grow close to neighboring device leads and are long enough to contact the leads, short circuiting may occur.

Tin whiskers are mainly formed by compressive stress which is caused by diffusion between a tin layer and a copper substrate, wherein intermetallic compounds are formed. The diffusion normally occurs along grain boundaries of the tin layer due to the higher diffusion coefficient of the tin atoms located thereat. The tin atoms flow along the direction of the compressive stress and pass through the surface of the oxide layer of the tin layer for tin whiskers to grow.

### BRIEF SUMMARY OF THE INVENTION

An embodiment of the invention provides a whisker-free coating structure. The whisker-free coating structure includes a substrate, a tungsten doped copper layer, and a lead-free tin layer. The tungsten doped copper layer overlays the substrate. The lead-free tin layer overlays the tungsten doped copper layer.

An embodiment of the invention provides a method for fabricating a whisker-free coating structure. First, a substrate is provided. Next, a tungsten doped copper layer is co-sputtered to overlay the substrate utilizing vacuum magnetron sputter deposition. Finally, a lead-free tin layer is formed overlaying the tungsten doped copper layer.

Note that further scope of the applicability of the invention will become apparent from the detailed descriptions given hereinafter. It should be understood however, that the detailed descriptions and specific examples, while indicating preferred embodiments of the invention, are given by way of illustration only, as various changes and modifications within the spirit and scope of the invention will become apparent to those skilled in the Art from the detailed descriptions.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 shows a cross-section of a whisker-free coating structure of a preferred embodiment of the invention;

FIGS. 2A and 2B show secondary-electron image photographs of no tin whiskers growth of a sample of Example 1 in an accelerated test under an environmental temperature of 60° C. for 60 hours;

FIGS. 3A and 3B show secondary-electron image photographs of tin whiskers growth of a sample of Comparative Example 1 in an accelerated test under an environmental temperature of 60° C. for 60 hours; and

FIG. 4 shows a schematic view of a magnetron sputtering equipment for the formation of the tungsten doped copper layer of the preferred embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

Next, the concepts and specific modes of the invention are described by the embodiments and the attached drawings in detail. In the drawings or description, similar elements are indicated by similar reference numerals and/or letters. Further, the element shape or thickness in the drawings can be expanded for simplification or convenience of indication. Moreover, elements which are not shown or described can be in every form known by those skilled in the art.

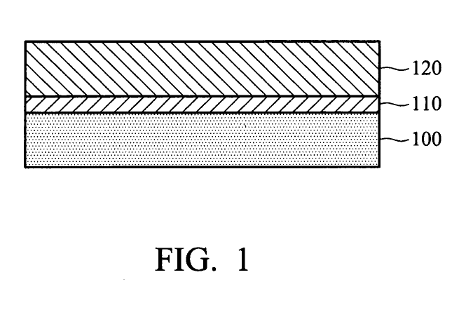

First, referring to FIG. 1, a cross-section of a whisker-free coating structure of a preferred embodiment of the invention is shown. The whisker-free coating structure comprises a substrate 100, a tungsten doped copper layer 110, and a lead-free tin layer 120.

The substrate 100 can be a silicon substrate, a copper foil substrate, or a lead-frame. The silicon substrate can be a silicon wafer, an epitaxial layer overlaying a silicon wafer, a silicon-on-insulator (SOI) layer overlaying a silicon wafer, a thin film transistor silicon layer overlaying a silicon wafer, or the like. Alternatively, the substrate 100 may be formed by other semiconductor materials. The copper foil substrate can be an electrodeposited copper foil (ED foil) or a rolled annealed copper foil (RA foil) formed by cold work, such as rolling, and annealing. Moreover, the lead-frame can be a lead-frame for common lead packages or quad flat non-lead (QFN) packages.

Regarding the tungsten doped copper layer 110 overlaying the substrate 100, tungsten and copper can be considered as mutually insoluble metals. Therefore, the tungsten doped copper layer 110 is formed by co-sputtering to dope tungsten into the copper. In this embodiment, a tungsten concentration in the tungsten doped copper layer 110 is preferably between 0.3 and 8.2 weight percent of the tungsten doped copper layer 110. When the tungsten concentration in the tungsten doped copper layer 110 is lower than 0.3 weight percent of the tungsten doped copper layer 110, the effect suppressing the whisker growth in the tin layer overlaying the tungsten doped copper layer 110 is limited. When the tungsten concentration in the tungsten doped copper layer 110 is higher than 8.2 weight percent of the tungsten doped copper layer 110, the electrical resistivity value of the tungsten doped copper layer 110 is increased, and the advantages of utilizing copper as the conductive layer may be hindered or limited.

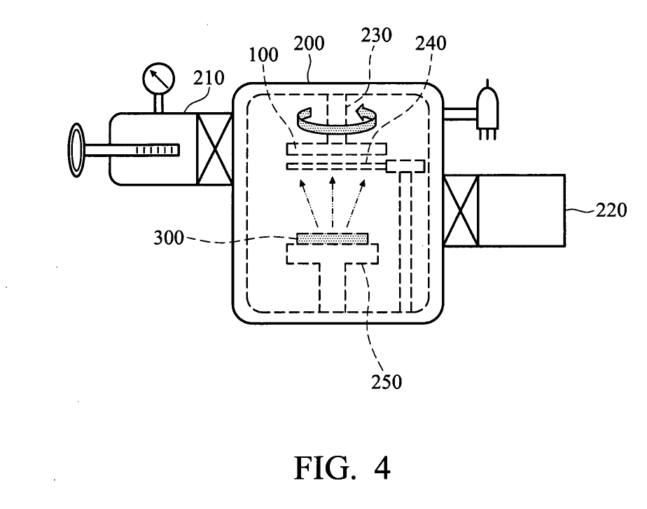

In this embodiment, the tungsten doped copper layer 110 is formed by a magnetron sputter deposition process performing co-sputtering of tungsten and copper. Referring to FIG. 4, for example, an appropriate surface cleaning process can be performed on the substrate 100, followed by placing the substrate 100 in a spin table 230 in a chamber 200 of a magnetron sputtering equipment via a load region 210. At this time, a target 300 is provided overlaying a target pedestal 250 in the chamber 200. Further, a mask layer may be preformed overlaying the substrate 100 when utilizing the lift-off to form the patterned tungsten doped copper layer 110.

Next, gas in the chamber 200 is exhausted by a turbo pump 220 until the air pressure (vacuity) in the chamber 200 is below 7×10⁻³ torr, and then high pure argon is introduced into the chamber 200. Next, a co-sputtering process is performed under a pressure of between 10⁻³ torr and 10⁻² torr. Particles sputtered from the target 300 hit and attach to the substrate 100. The thickness of the tungsten doped copper layer 110 can be controlled by the sputtering period determined by the open and close switching of a shutter 240. In this embodiment, the formed tungsten doped copper layer 110 is between 2 nm and 500 nm thick. In other embodiments, the thickness of the tungsten doped copper layer 110 can be beyond the range between 2 nm and 500 nm as required. For control of tungsten concentrations in the tungsten doped copper layer 110, reference may be made to the deposition conditions between a pure copper target and a tungsten target disclosed by Taiwan patent publication No. 00574431 (hereafter referred as TW 574431). For other sputtering conditions, reference may be made to Table 2 in TW 574431 or Table 2 in Taiwan patent issue No. I237328 (hereafter referred as TW 1237328).

After the co-sputtering process for formation of the tungsten doped copper layer 110 is completed, an annealing process can be optionally performed as required, and the annealing conditions can follow the conditions disclosed in pages 5 and 6 of “descriptions of the invention” of TW574431. Further, when a functional pattern such as a wiring pattern or the like is required, the tungsten doped copper layer 110 can be patterned by a lift-off, lithography, or the like process.

Regarding this embodiment of a lead-free tin layer 120, the lead-free tin layer 120 is a matte tin layer of pure tin formed by electroplating, overlaying the tungsten doped copper layer 110. In other embodiments, the lead-free tin layer 120 may be pure tin, tin-copper lead-free solder alloys, tin-silver-copper lead-free solder alloys, or the like formed by other known processes overlaying the tungsten doped copper layer 110. In some embodiments, a tin concentration in the lead-free tin layer 120 can be 95 weight percent of the lead-free tin layer 120 or greater.

The thickness of the lead-free tin layer 120 may depend on applications thereof and is not specifically limited. In this embodiment, the lead-free tin layer 120 may be between 3 μm and 60 μm thick.

Several examples of the whisker-free coating structure and method for fabricating the same are listed as follows. Note that the materials and processes described in these examples are not intended to limit the scope of the invention. Those skilled in the art will recognize the possibility of using various materials and processes to achieve the described whisker-free coating structure and method for fabricating the same. For example, a matte tin layer of pure tin formed by electroplating is utilized as the lead-free tin layer in the subsequent examples to describe the effects of the invention, but the effects can also be achieved by utilization of lead-free tin layers of other compositions.

### EXAMPLE 1

An approximately 300 nm thick tungsten doped copper layer with a tungsten concentration of 1.3 atomic percent (3.67 weight percent) of the tungsten doped copper layer was coated overlaying a silicon substrate, and then a matte tin layer was formed overlaying the tungsten doped copper layer by electroplating with an electric current density of 5ASD for two minutes. The formed matte tin layer was approximately 3800 nm thick. A surface observation was performed on the surface of the coating (matte tin layer) of the sample immediately after formation of the matte tin layer. No tin whiskers were observed on the sample according to secondary electron images (SEI).

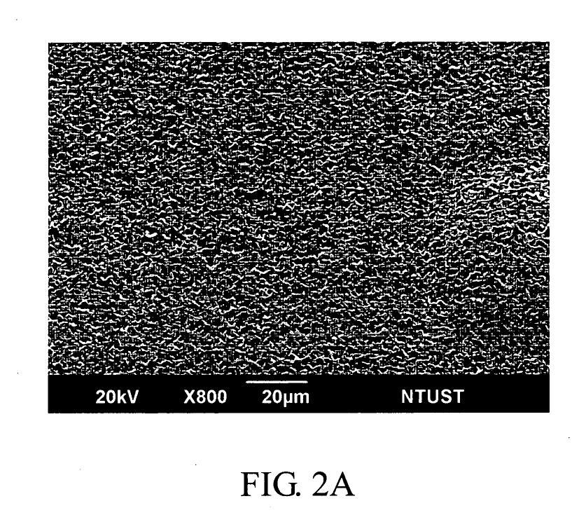

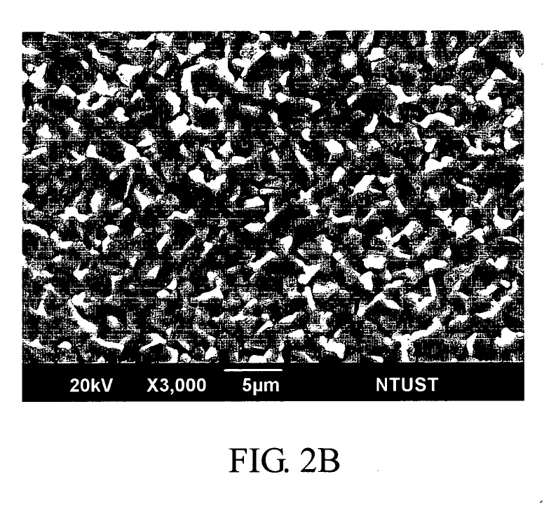

Next, an accelerated test was performed on the sample, wherein the sample was disposed under an environmental temperature of 60° C. for 60 hours. Afterward, a surface observation was performed on the surface of the coating (matte tin layer) of the sample immediately after formation of the matte tin layer. No tin whiskers were observed on the sample according to secondary electron images (SEI) as shown in FIGS. 2A and 2B. FIGS. 2A and 2B show images of different zoom-in magnifications. The zoom-in magnifications shown in FIGS. 2A and 2B are set values of the secondary electron image equipment, and not the zoom-in magnifications of the photographs themselves.

### COMPARATIVE EXAMPLE 1

A matte tin layer was formed overlaying a pure copper substrate by electroplating with an electric current density of 5 ASD (A/dm²) for two minutes. The formed matte tin layer was approximately 3800 nm thick. A surface observation was performed on the surface of the coating (matte tin layer) of the sample immediately after formation of the matte tin layer. No tin whiskers were observed on the sample according to secondary electron images (SEI).

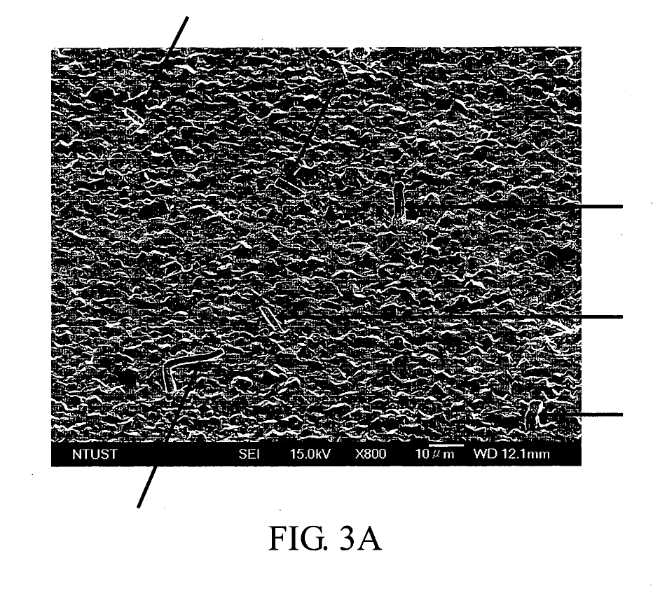

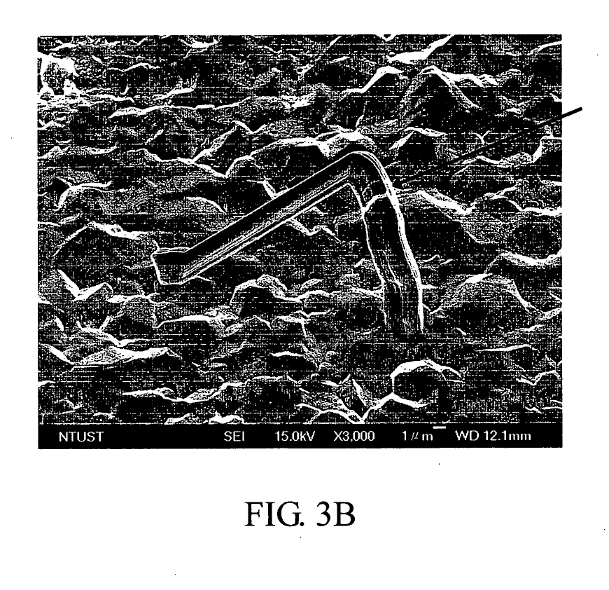

Next, an accelerated test was performed on the sample, wherein the sample was disposed under an environmental temperature of 60° C. for 60 hours. Subsequently, a surface observation was performed on the surface of the coating (matte tin layer) of the sample immediately after formation of the matte tin layer. Tin whiskers were observed on the sample according to secondary electron images (SEI) as shown in FIGS. 3A and 3B, wherein the structures indicated by arrow marks are tin whiskers. FIGS. 3A and 3B show images of different zoom-in magnifications. The zoom-in magnifications shown in FIGS. 3A and 3B are set values of the secondary electron image equipment, and not the zoom-in magnifications of the photographs themselves.

As described and shown, whisker growth in the lead-free tin layers can be effectively suppressed by the whisker-free coating structure of the invention and method for fabricating the same.

While the invention has been described by way of example and in terms of preferred embodiment, it is to be understood that the invention is not limited thereto. To the contrary, it is intended to cover various modifications and similar arrangements (as would be apparent to those skilled in the Art). Therefore, the scope of the appended claims should be accorded the broadest interpretation so as to encompass all such modifications and similar arrangements.

What is claimed is:

1. A whisker-free coating structure, comprising:
a substrate;
a tungsten doped copper layer overlaying the substrate; and
a lead-free tin layer overlaying the tungsten doped copper layer.

2. The structure as claimed in claim 1, wherein the substrate comprises a silicon substrate, a copper foil substrate, and a lead-frame.

3. The structure as claimed in claim 1, wherein a tungsten concentration in the tungsten doped copper layer is between 0.3 and 8.2 weight percent of the tungsten doped copper layer.

4. The structure as claimed in claim 1, wherein the tungsten doped copper layer is between 2 and 500 nm thick.

5. The structure as claimed in claim 1, wherein the lead-free tin layer comprises pure tin, tin-copper lead-free solder alloys, and tin-silver-copper lead-free solder alloys.

6. The structure as claimed in claim 1, wherein a tin concentration in the lead-free tin layer is 95 weight percent of the lead-free tin layer or greater.

7. The structure as claimed in claim 1, wherein the lead-free tin layer is a matte tin layer.

8. The structure as claimed in claim 1, wherein the lead-free tin layer is between 3 and 60 μm thick.

9. A method for fabricating a whisker-free coating structure, comprising: providing a substrate; co-sputtering a tungsten doped copper layer overlaying the substrate utilizing vacuum magnetron sputter deposition; and forming a lead-free tin layer overlaying the tungsten doped copper layer.

10. The method as claimed in claim 9, wherein the lead-free tin layer is formed by electroplating.

11. The method as claimed in claim 9, wherein the substrate comprises a silicon substrate, a copper foil substrate, and a lead-frame.

12. The method as claimed in claim 9, wherein a tungsten concentration in the tungsten doped copper layer is between 0.3 and 8.2 weight percent of the tungsten doped copper layer.

13. The method as claimed in claim 9, wherein the tungsten doped copper layer is between 2 and 500 nm thick.

14. The method as claimed in claim 9, wherein the lead-free tin layer comprises pure tin, tin-copper lead-free solder alloys, and tin-silver-copper lead-free solder alloys.

15. The method as claimed in claim 9, wherein a tin concentration in the lead-free tin layer is 95 weight percent of the lead-free tin layer or greater.

16. The method as claimed in claim 9, wherein the lead-free tin layer is a matte tin layer.

17. The method as claimed in claim 9, wherein the lead-free tin layer is between 3 and 60 μm thick.
